(19) United States
(12) Patent Application Publication
(10) Pub. No.: US 2025/0393281 A1
(43) Pub. Date: Dec. 25, 2025

(54) Low Saturation Voltage BJT with Enhanced Packing Flexibility

(71) Applicant: Diodes Incorporated, Plano, TX (US)

(72) Inventors: Matthew Mott, Oldham (GB); Paul Jerred, Oldham (GB); Lee Riley, Oldham (GB)

(21) Appl. No.: 19/248,145

(22) Filed: Jun. 24, 2025

(30) Foreign Application Priority Data
Jun. 25, 2024 (GB) 2409109.2

(51) Int. Cl. H10D 64/23; H01L 23/528; H10D 10/01; H10D 10/40; H10D 64/27

(52) U.S. Cl. CPC H10D 64/231; H01L 23/528; H01L 23/5283; H10D 10/058; H10D 10/40; H10D 64/281

(57) ABSTRACT

A bipolar junction transistor (BJT) comprising a semiconductor region and a plurality of metal contacts, located on a top surface of the semiconductor region, where the plurality of metal contacts comprise one or more first metal contacts that are in contact with one or more emitter regions and one or more second metal contacts that are in contact with an upper surface of a body region of the semiconductor region. One or more insulating structures are located on the top surface of the semiconductor region, where the insulating structures isolate the one or more first metal contacts from the one or more second metal contacts. A metal layer is located over the insulating structures, where the metal layer is in contact with one or more first metal contacts and is isolated from the one or more second metal contacts by the insulating structures.

### CROSS-REFERENCE TO RELATED APPLICATIONS

This patent application claims priority to United Kingdom Patent Application No. 2409109.2, filed on Jun. 25, 2024, and entitled “Bipolar Junction Transistor,” which is hereby incorporated by reference herein as if reproduced in its entirety.

### TECHNICAL FIELD

The present disclosure relates to a semiconductor device and a method of manufacturing a semiconductor device. Particularly, but not exclusively, the disclosure relates to a bipolar junction transistor (BJT) semiconductor device.

### BACKGROUND

A bipolar junction transistor (BJT) is a three-terminal semiconductor power device, which comprises two pn-junctions formed by sandwiching a semiconductor layer of one conductivity type (p-type or n-type) between a pair of semiconductor regions of the opposite conductivity type.

The latest generation of bipolar junction transistors offer lower specific on-resistance than metal-oxide-semiconductor field-effect transistors (MOSFETs). The ruggedness to electrostatic discharge (ESD) of bipolar junction transistors, along with their very low specific on-resistance, also make them very cost effective alternatives to MOSFETs.

FIG. 1(a) shows a top view of a bipolar junction transistor (BJT), and FIG. 1(b) shows a top view of a BJT device. The tracks to the emitter and base contacts are formed in an interdigitated arrangement, within a single layer metal and with separate emitter and base bonding areas.

It is advantageous to reduce power loss and increase efficiency within a packaged BJT device when operating as a saturated switch. Two factors accounting for power loss are the combined specific area emitter to collector resistance of the BJT device and the resistance of the package internal wire connectors.

Existing devices are unable to enlarge the BJT emitter bond pad area to accommodate low resistance multiple bond wires or ribbon bond connection without reducing the active area and increasing the specific area resistance of the BJT device.

The device of the present disclosure addresses the above-recited problem of reducing power loss and increasing efficiency within a packaged BJT device.

### SUMMARY

Technical advantages are generally achieved, by embodiments of this disclosure which describe low saturation voltage BJT with enhanced packing flexibility.

Aspects and preferred features are set out in the accompanying claims.

Embodiments of the present disclosure relate to a bipolar junction transistor (BJT). The BJT includes: a semiconductor region, comprising: a drift region of a first conductivity type; a body region of a second conductivity type, opposite to the first conductivity type, disposed over the drift region; one or more emitter regions of a first conductivity type disposed within the body region; and a plurality of metal contacts, located on a top surface of the semiconductor region, wherein the plurality of metal contacts comprise one or more first metal contacts that are in contact with the one or more emitter regions and one or more second metal contacts that are in contact with an upper surface of the body region; one or more insulating structures located on a top surface of the semiconductor region, wherein the insulating structures isolate the one or more first metal contacts from the one or more second metal contacts; and a metal layer located over the insulating structures, wherein the metal layer is in contact with one or more first metal contacts and is isolated from the one or more second metal contacts by the insulating structures.

MOSFET transistors are voltage controlled in contrast to bipolar transistors, which are current controlled. This important difference affects the materials that can be used for the gate and base electrodes of MOSFETs and BJTs. This means that, unlike MOSFETs, which use doped polysilicon electrodes for the gate, the base and emitter electrodes of BJTs are generally formed of high conductivity metals such as Aluminum. High conductivity metals tend to be soft and therefore easily deformed by bonding forces, unlike polysilicon, which is harder. Additionally, existing BJTs, such as that shown in FIG. 1(a) and FIG. 1(b) generally have tracks to the emitter and base contacts formed in an interdigitated arrangement, which cannot be used with ribbon bond technology. The configuration of the herein disclosed device provides isolation between the base and emitter contacts, and allows the base contact to be formed outside of the active area of the device.

Due to these differences, existing matrix BJTs are not suitable for ribbon bonding over the active area.

The structure of the herein disclosed device allows low resistance ribbon bond technology to be used, thereby reducing package resistance. This provides a low saturation voltage BJT with enhanced packaging flexibility.

The load bearing interlayer dielectric structure of the herein disclosed device allows ribbon bond technology to be used on a matrix bipolar transistor, by keeping the base and emitter metal tracks isolated from each other.

The one or more first metal contacts and the one or more second metal contacts may be laterally spaced from each other in a first direction. The one or more second metal contacts may be vertically spaced from the metal layer in a second direction, where the second direction is perpendicular to the first direction. This provides a two-layer metal structure, with the metal layer vertically separated from the base metal contacts.

As well as withstanding bonding forces, the two-layer metal structure means that the area of the device that can be used as an emitter bond area is significantly enlarged without sacrificing the active area of the device or without increasing specific area resistance.

The bipolar junction transistor may be configured such that, when in use, current flows vertically between the one or more first metal contacts and the metal layer, and current flows within the one or more second metal contacts laterally through the bipolar junction transistor. In other words, the bipolar junction transistor may be a vertical bipolar junction transistor.

There is no requirement for interdigitated connections to first metal contacts (emitter contacts) to be located between connections to second metal contacts (base contacts). Instead, connection to first metal contacts can be made vertically through the metal layer, and connections to the second metal contacts can be made laterally through a lower layer of the device to the metal layer. This means that, in comparison to state-of-the-art devices, there is no lateral voltage drop across adjacent base contacts and emitter contacts.

As each of the first metal contacts (the emitter contacts) are connected vertically to the metal layer, this improves the uniformity of the connection to the emitter contacts and allows for an optimum emitter to base bias across the device.

The bipolar junction transistor may comprise a base terminal connection. The one or more second metal contacts may be connected to the base terminal via a metal track extending along a perimeter of the bipolar junction transistor. The metal track may extend substantially around a perimeter of the device, or may only extend partially around a perimeter of the device. By connecting the second metal contacts to the base terminal connection via a metal track around the perimeter of the device, the connections to the second metal contacts can be more uniform and can be optimized.

Each second metal contact of the one or more second metal contacts may be connected to the metal track via a plurality of connections extending in at least two different directions.

Each second metal contact of the one or more second metal contacts may be directly connected to a portion of the metal track extending along a side of the bipolar junction transistor that is closest to said each second metal contact of the one or more second metal contacts. This allows for shorter connections to the second metal contacts.

The one or more insulating structures may comprise a plurality of first insulating regions located on a top surface of the semiconductor region. Each first insulating region may be located laterally between a first metal contact of the one or more first metal contacts and a second metal contact of the one or more second metal contacts. The one or more insulating structures may further comprise one or more dielectric regions located over the one or more second metal contacts. The dielectric regions may be at least partly located over the plurality of first insulating regions.

The one or more dielectric regions may overlap an upper surface of the one or more first metal contacts. In other words, at least a portion of the one or more dielectric regions may overhang a top surface of the first metal contacts. This provides strength to the device.

The one or more dielectric regions may comprise an upper dielectric region supported by two or more laterally spaced columnar structures. Each columnar structure may be formed over a first insulating region.

Mechanical support to the dual-layer metal electrode structures to withstand higher bonding forces is achieved by the laterally spaced columnar structures, which act as support pillars within the interlayer dielectric region.

A width of the two or more columnar structures may be at least 2 μm. This provides strength to the device.

A spacing between adjacent columnar structures may be 5 μm to 20 μm. More preferably, a spacing between adjacent columnar structures may be 12 μm.

An upper surface of the one or more dielectric regions may be planarized. This allows a substantially flat metal layer to be formed over the dielectric region, and improves the ease of contact to the metal layer.

The insulating structures may be formed of silicon dioxide. This provides strength to the device to withstand bonding forces.

The metal layer may have a larger surface area than the one or more first metal contacts. This allows a ribbon bond to be connected to the metal layer.

The bipolar junction transistor may further comprise a ribbon bond formed over the metal layer.

The bipolar junction transistor may further comprise a clip bond formed over the metal layer.

An edge length of a top surface of the metal layer and/or the active area of the semiconductor chip may have a length of greater than 0.25 mm, more preferably greater than 0.5 mm, more preferably greater than 1 mm.

The ribbon bond may have a width of greater than 500 μm, more preferably greater than 750 μm. The ribbon bond may have an uncompressed height of greater than 50 μm, more preferably greater than 100 μm. The ribbon bond may have an area greater than 0.1 mm², more preferably greater than 0.2 mm² in contact with the metal layer.

The bipolar junction transistor may further comprise a clip bond formed over the metal layer. The clip bond may have a width of greater than 500 μm, more preferably greater than 750 μm. The clip bond may have an uncompressed height of greater than 100 μm, more preferably greater than 150 μm. The ribbon bond may have an area greater than 0.2mm², more preferably greater than 0.4mm² in contact with the metal layer.

A spacing between adjacent second metal contacts of the one or more second metal contacts may be between 20 μm to 100 μm. More preferably, a spacing between adjacent second metal contacts of the one or more second metal contacts may be between 35 μm to 50 μm.

An emitter terminal connection may be formed on an upper surface of the device over the metal layer. The emitter terminal connection may extend substantially over the active area of the device.

The bipolar junction transistor may further comprise a base terminal connection formed on an upper surface of the device. The base terminal connection may not extend over the metal layer.

Embodiments of the present disclosure relate to a manufacturing method of a bipolar junction transistor (BJT). The manufacturing method of a bipolar junction transistor (BJT) includes: forming a semiconductor region, comprising: a drift region of a first conductivity type; a body region of a second conductivity type, opposite to the first conductivity type, disposed over the drift region; one or more emitter regions of a first conductivity type disposed within the body region; and forming a plurality of metal contacts, located on a top surface of the semiconductor region, wherein the plurality of metal contacts comprise one or more first metal contacts that are in contact with the one or more emitter regions and one or more second metal contacts that are in contact with an upper surface of the body region; forming one or more insulating structures located on a top surface of the semiconductor region, wherein the insulating structures isolate the one or more first metal contacts from the one or more second metal contacts; forming a metal layer located over the insulating structures, wherein the metal layer is in contact with the one or more first metal contacts and is isolated from the one or more second metal contacts by the insulating structures.

Forming the one or more insulating structures may comprise forming one or more dielectric regions comprising an upper dielectric region supported by two or more laterally spaced columnar structures. The upper dielectric region may have a thickness that is at least half the width of the columnar structures. This ensures that breadloafing, which may occur when depositing the dielectric region, allows the gap between adjacent metal contacts to be filled to form the support pillars.

After forming the one or more dielectric regions, the method may further comprise planarizing an upper surface of the upper dielectric region.

The devices of the present disclosure are advantageous over state-of-the-art devices for at least the following reasons: the size of the device can be reduced while having improved high current performance; ribbon bonding can be implemented on a matrix bipolar junction transistor. This improves the saturation collector-emitter voltage (Vce(sat)), and the specific area ON resistance; current distribution across the matrix bipolar junction transistor is improved by means of the dual-layer metal structure, including a base connected metal mesh layout and emitter connected top metal layers. This improves switching performance.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings. It is important to acknowledge that the proportional representation of various structures may not be strictly adhered to. In practice, for the sake of elucidation, the dimensions of these structures may be deliberately exaggerated or minimized to enhance clarity in explanation.

FIG. 1(a) shows a top view of an example bipolar junction transistor (BJT) according to some embodiments of the present disclosure;

FIG. 1(b) shows an alternative top view of an example bipolar junction transistor (BJT) according to some embodiments of the present disclosure;

FIG. 2 shows a cross-sectional view of a BJT according to some embodiments of the present disclosure;

FIG. 3 shows a scanning electron microscope image of a cross-sectional view of a BJT according to some embodiments of the present disclosure;

FIG. 4(a) shows a top-view of a BJT according to some embodiments of the present disclosure;

FIG. 4(b) shows an alternative top-view of a BJT according to some embodiments of the present disclosure;

FIG. 5 shows a magnified top-view of the BJT shown in FIG. 4(a) and FIG. 4(b) according to some embodiments of the present disclosure;

FIG. 6 shows a further magnified top-view of the BJT shown in FIG. 5 according to some embodiments of the present disclosure;

FIG. 7(a) shows a cross-sectional view along line D-D′ of the BJT device shown in FIG. 6 according to some embodiments of the present disclosure;

FIG. 7(b) shows an alternative cross-sectional view along the diagonal line C-C′ of the BJT device shown in FIG. 6 according to some embodiments of the present disclosure;

FIG. 8 shows a magnified top-view of an alternative BJT according to some embodiments of the present disclosure;

FIG. 9 shows a magnified top-view of the base pad area of the BJT shown in FIG. 4(a) and FIG. 4(b) according to some embodiments of the present disclosure;

FIG. 10(a) shows a cross-sectional view along the line E-E′ through the BJT device shown in FIG. 9 according to some embodiments of the present disclosure;

FIG. 10(b) shows an alternative cross-sectional view along the line E-E′ through the BJT device shown in FIG. 9 according to some embodiments of the present disclosure;

FIG. 11(a) shows schematically a top-view and side view of ribbon bonding to a BJT device as disclosed herein according to some embodiments of the present disclosure;

FIG. 11(b) shows schematically a top-view and side view of clip bonding to a BJT device as disclosed herein according to some embodiments of the present disclosure;

FIG. 11(c) shows a side-view of a clip bond, such as that shown in FIG. 11(b) according to some embodiments of the present disclosure; and

FIG. 12 illustrates a flow chart of a method for manufacturing a BJT device according to some embodiments of the present disclosure.

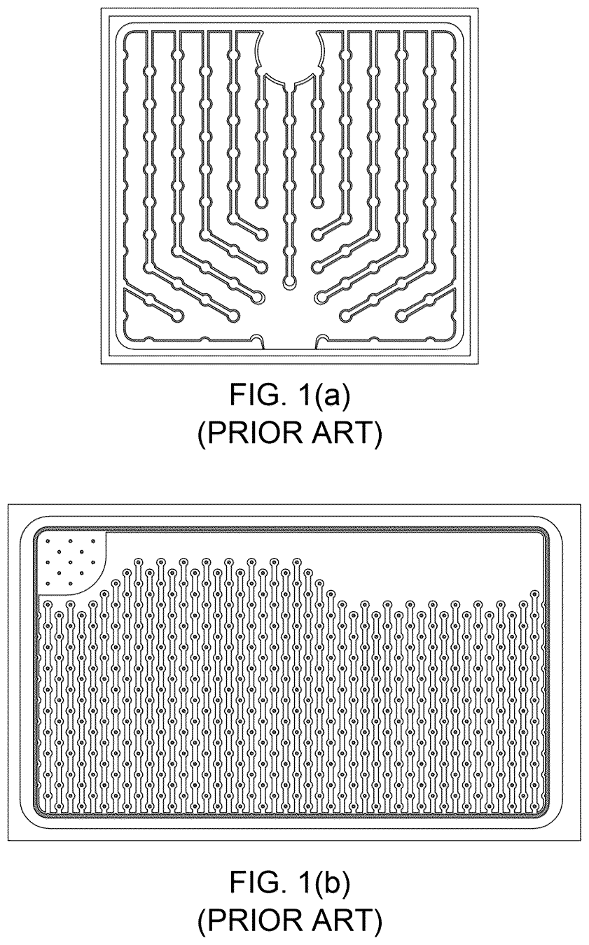

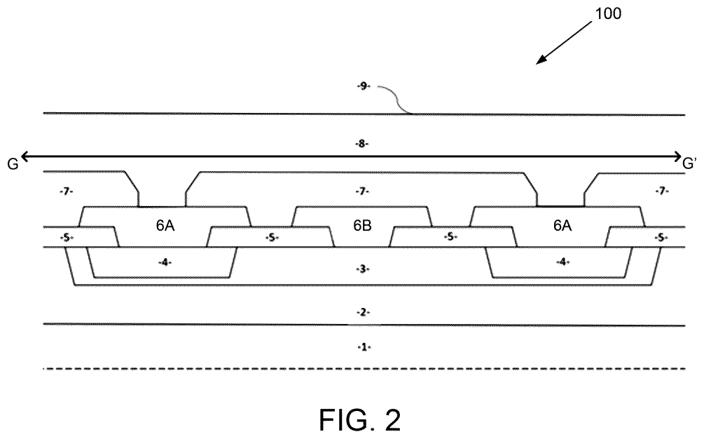

The same or similar components are marked with the same reference numerals and symbols in the drawings and detailed description. The figures are drawn to clearly illustrate the relevant aspects of the embodiments and are not necessarily drawn to scale. Embodiments of the present disclosure will be readily understood from the following detailed description in conjunction with the accompanying drawings.

### DETAILED DESCRIPTION OF ILLUSTRATIVE EMBODIMENTS

The following disclosure provides numerous different embodiments or examples for implementing the various features of the provided subject matter. Specific instances of components and configurations are described below. Of course, these are merely examples and are not intended to limit the scope of the present disclosure. In this disclosure, references to the formation of a first feature above or on top of a second feature may include embodiments where the first and second features are formed in direct contact, as well as embodiments where additional features are formed between the first and second features, allowing for cases where the first and second features do not directly contact each other. Additionally, the disclosure may repeat reference numerals and/or letters across various instances. This repetition is for simplicity and clarity and does not indicate any relationship between the various embodiments and/or configurations being discussed.

Further, it should be understood that various changes, substitutions and alterations can be made herein without departing from the spirit and scope of this disclosure as defined by the appended claims. One or more features from one or more of the following described embodiments may be combined to create alternative embodiments not explicitly described, and features suitable for such combinations are understood within the scope of this disclosure. It is therefore intended that the appended claims encompass any such modifications or embodiments.

The embodiments of the present disclosure are discussed in detail below. However, it should be understood that this disclosure offers many applicable concepts that can be embodied in a wide variety of specific environments. The specific embodiments discussed are merely illustrative and do not limit the scope of the present disclosure.

FIG. 2 shows a cross-section of a vertical bipolar junction transistor (BJT) device according to an embodiment of the disclosure. In this embodiment, the BJT device 100 includes an n-type voltage sustaining region or drift region 2 over a collector layer 1 of a semiconductor substrate. The collector layer 1 is a doped n-type region of the substrate, having a higher doping concentration than the drift region 2. Located above the drift region 2, there is provided a p-type base region (which may be referred to as a p-well or p-body region) 3.

Disposed within the base region 3, a plurality of n+emitter contact regions 4 of the emitter are formed. The emitter contact regions 4 (referred to as emitter regions) have a higher doping concentration than the drift region 2. The emitter contact regions 4 are laterally spaced from each other within the base region 3. Both the emitter contact regions 4 and the base region 3 are located completely above the collector layer 1.

The semiconductor substrate includes the collector layer 1, the drift layer 2, the base region 3, and the emitter regions 4. A plurality of insulating regions 5 are formed over a top surface of the semiconductor substrate. The insulating regions 5 are each disposed at least partly over the emitter contact regions 4. The insulating regions 5 are laterally spaced from each other, and each insulating region 5 is in contact with a portion of a top surface of an emitter contact region 4 and a portion of a top surface of the base region 3. In some embodiments, the insulating regions 5 are formed of an oxide region.

A plurality of metal contact regions (also referred to as metal contacts) 6 are formed over the top surface of the semiconductor substrate. The metal contact regions 6 are laterally spaced from each other. The metal contact regions 6 may be formed of a patterned metal layer. A first plurality of contacts 6A of the metal contact regions 6 (also referred to as the emitter electrodes) are located over the emitter contact regions 4 such that each contact of the first plurality of contacts 6A is in contact with one emitter contact region 4. The first plurality of contacts 6A may partially extend over a top surface of one or more insulating regions 5. A second plurality of contacts 6B of the metal contact regions 6 (also referred to as the base electrodes) are located over the body region 3 such that each contact of the second plurality of contacts 6B is in contact with the body region 3. The emitter electrodes 6A are formed in the same plane as the base electrodes 6B. The second plurality of contacts 6B may also partially extend over a top surface of one or more insulating regions 5.

The insulating regions 5 are located such that the insulating regions 5 electrically isolate contacts of the first plurality of contacts 6A from adjacent contacts of the second plurality of contacts 6B.

One or more further insulating regions (in this example, an interlayer dielectric) 7 are located at least partially over some of the insulating regions 5 and the first plurality of contacts 6A. Each interlayer dielectric region 7 completely covers one of the second plurality of contacts 6B and extends down between adjacent contacts of the first plurality of contacts 6A and contacts of the second plurality of contacts 6B, such that a lower surface of the interlayer dielectric region 7 is in contact with a plurality of the insulating regions 5. The interlayer dielectric region 7, in conjunction with the insulating regions 5 it is in contact with, forms a columnar structure of support pillars that isolates the contact 6B of the second plurality of contacts from the adjacent contacts 6A of the first plurality of contacts it is located between. The interlayer dielectric region 7 may partially extend over a top surface of one or more contacts of the first plurality of contacts 6A. This overhang portion of the interlayer dielectric region 7 increases the strength of the interlayer dielectric region 7 and the device.

A metal contact layer 8 is located over the interlayer dielectric 7 and the metal contact regions 6. The metal contact layer 8 completely covers the interlayer dielectric region 7 and extends down between adjacent interlayer dielectric regions 7, such that a lower surface of the metal contact layer 8 is in contact with the first plurality of contacts 6A.

The plurality of metal contact regions 6 may be formed of a first metal. The metal contact layer 8 may be formed of a second metal. The first metal and the second metal may be the same metal, or they may be different metals.

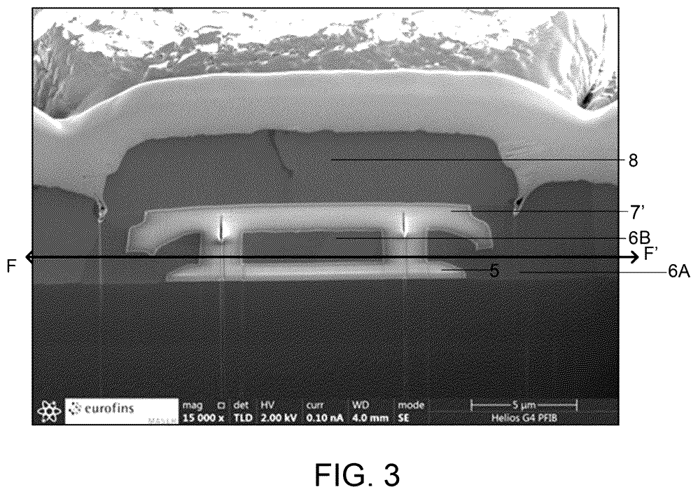

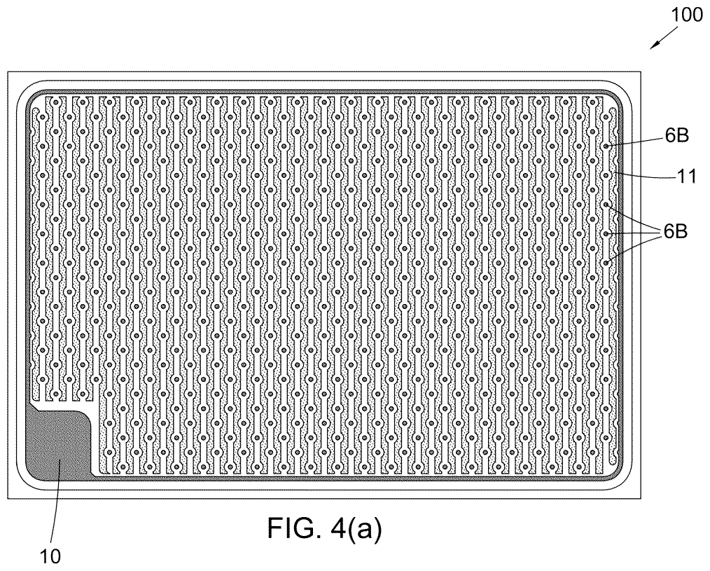

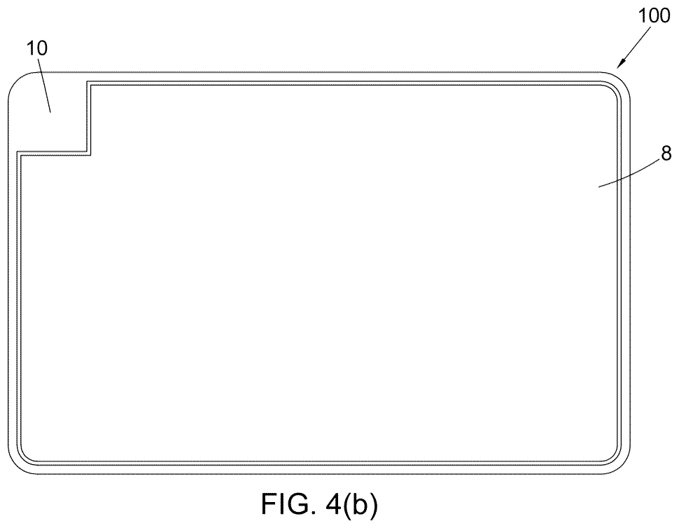

The conductivity and flow of the metal used when forming the metal contact layer 8 creates vias to the metal contact regions 6A, as shown in FIGS. 3, 4(a), and 4(b). Alternatively, in some examples a plug (for example, a Tungsten plug) may be used to connect the two metals.

A further metal layer 9 may be formed over the metal contact layer 8. In some examples, the further metal layer 9 may be a ribbon bond formed over a top surface of the device or may be connected to a ribbon bond. In this example, the ribbon bond includes an aluminum or gold ribbon bond. Due to the large cross-section of a ribbon bond compared to wire bonding, it can carry higher currents. For example, in a BJT device as disclosed, the use of a ribbon bond can increase the current performance by up to 10 A.

In the herein disclosed device, multiple silicon dioxide pillars from the interlayer dielectric regions 7 contribute to supporting the ball or ribbon bond. The herein disclosed BJT device can therefore withstand increased forces caused by ribbon bonding.

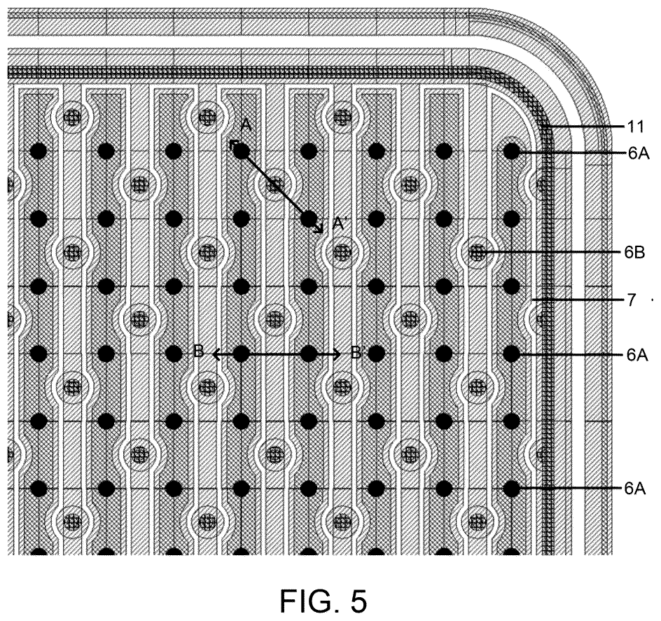

It will be appreciated that FIG. 2 shows a cross-section through one portion of the BJT, and that the cross-section is not constant through the whole device. For example, FIG. 2 illustrates a cross-section through the device shown in FIG. 5 across the diagonal line A-A′.

FIG. 3 shows a scanning electron microscope image of a cross-section of a BJT according to an embodiment of the disclosure. The BJT device shown in FIG. 3 may be the same as the device shown in FIG. 2, although the cross-section shown may be taken across a different area of the device. Many of the features therefore carry the same reference numerals as those of FIG. 2. In some embodiments, FIG. 3 illustrates a cross-section through the device shown in FIG. 5 across the line B-B′.

In the example shown in FIG. 3, the interlayer dielectric region 7 and the insulating regions 5 may be silicon dioxide, deposited via plasma-enhanced chemical vapor deposition (PECVD) using a tetraethyl orthosilicate (TEOS) precursor. The use of TEOS for the interlayer dielectric region 7 gives more conformal step coverage.

When depositing the interlayer dielectric region 7, the deposition is performed such that an upper dielectric region located over the support pillars has a thickness that is at least half the width of the support pillars. This ensures that breadloafing, which occurs when depositing the dielectric region, causes the gap between adjacent metal contacts 6A, 6B to be filled to form the support pillars.

An upper surface of the interlayer dielectric region 7 is then planarized such that an upper surface of the interlayer dielectric region 7 is substantially flat. This planarized upper surface of the interlayer dielectric region 7 transfers bonding forces to the multiple support pillars provided underneath the upper surface. The interlayer dielectric region 7 provides support for the base contact 6B underneath, and isolates the base metal contact 6B from the emitter contact 6A and the metal layer 8. The support pillars formed by the interlayer dielectric region 7 and insulating regions 5 (in this example, formed of silicon dioxide) are less compressible than the metal regions due to the absence of voids within the support pillars, and have a high density. This strengthens the device.

The spacing between adjacent metal contacts 6, the thickness of the support pillars and the sidewall angle improve the formation of dense support pillars. The configuration of the herein disclosed device allows the spacing between adjacent metal contacts 6 to be reduced compared to state-of-the-art devices. For example, adjacent base contacts 6B may be separated by 35 to 50 μm. The support pillars may have a depth or thickness of around 4 μm, and a width of the support pillars may be at least 2um. The sidewall angle (the angle of the metal contacts 6 and the horizontal plane) is generally between 5° and 15°. This off-vertical metal sidewall angle promotes the formation of void free support pillars when deployed in conjunction with conformal ILD (interlayer dielectric) deposition technology such as PECVD (plasma enhanced chemical vapor deposition).

The planarized surface of the interlayer dielectric region 7 allows the metal contact layer 8 to be substantially flat such that the ribbon bond can be connected to the metal contact layer 8. The mechanical bonding process used to attach a ribbon bond is generally a gentler and less harsh process on the device compared to wire bonding, as it spreads the mechanical stress over a larger surface area of the device. Alternatively, wire bonding or clip bonding may be used.

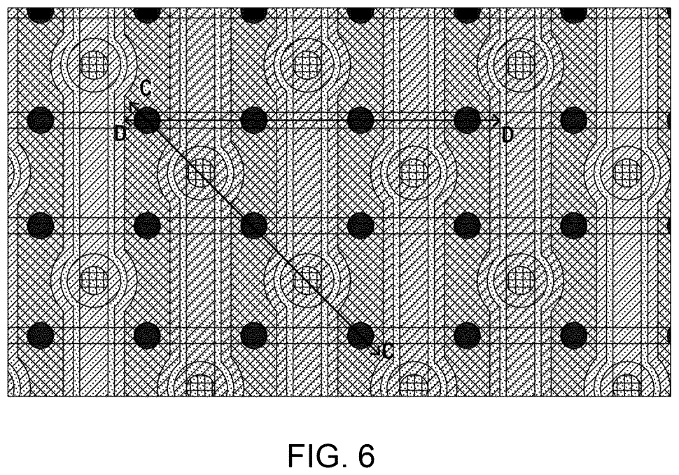

FIG. 4(a) shows a top-view of a BJT according to an embodiment of the disclosure, and FIG. 5 shows a magnified top-view of the BJT shown in FIGS. 4(a) and 4(b). FIG. 6 shows a further magnified view of the device of FIG. 5. The view shown in FIG. 4(a) may be a horizontal cross section through the device shown in FIG. 3 along line F-F′, where the upper metal contact layer has been omitted. The metal contacts 6B that are connected to the body region 3 (the base contacts) are arranged in a grid pattern of rows of metal contacts 6B. In this example, the rows are shown vertically. Each row of base contacts 6B are connected along the direction of the row of contacts 6B to a base pad 10 via a metal track 11. In the example shown, the base pad 10 is located at a periphery or edge of the device, and may be formed outside of the active area of the device. In this example, the base pad 10 is located on a corner region of the device. Although it will be understood that the base pad 10 could be located in a different region of the device.

While not shown in the figures, the connections between base contacts 6B within each row are formed in a lower layer of the device than the metal contact layer 8 such that the device has a dual layer metal structure. In state-of-the-art devices, a ribbon bond over a top surface of the device would short circuit the base contact 6B and the emitter contacts 6A, whereas the dual-layer metal structure allows the ribbon bond to be safely connected to the top surface of the device without causing a short.

During operation, current to the base contact 6B flows laterally through the device, while current to the emitter contact 6A flows vertically from the metal layer 8. There is no requirement for interdigitated connections to emitter contacts 6A to be located between connections to base contacts 6B. This means that, in comparison to state-of-the-art devices, there is no lateral voltage drop across adjacent base contacts 6B and emitter contacts 6A. This provides a single cell geometry that can be used for multiple applications without requiring as much customization as state-of-the-art devices.

In the example shown in FIGS. 4(a) and 5, the rows of base contacts 6B can be connected to the metal track 11 via connections running between a first side of the device and a second, opposite side of the device. In comparison to state-of-the-art devices in which base contacts are connected to the base pad along single-ended interdigitated connections, the base contacts 6B can be connected to two, opposite sides of the metal track 11. Therefore, the connections between the base contacts 6B and the metal track 11 are more uniform throughout the device. This improves the uniformity of the potential bias across the device and allows for quicker turn-off in regions of the device further from the base pad.

Similarly, as each of the emitter contacts 6A are connected vertically to the metal layer 8, this improves the uniformity of the emitter contacts and allows for an optimum emitter to base bias across the device. This also improves the turn-on speed of the device. This allows a larger device to be manufactured while still having quick turn-on and turn-off speeds. The switching speeds of the herein disclosed BJT devices can be comparable to MOSFETs.

The upper metal contact layer 8 connected to the metal contacts 6A that are connected to the emitter contact regions 4, extends over the surface of the device with the exception of the base contact 10 and the metal track 11, as shown in FIG. 4(b). In the view of FIG. 4(b), the upper metal layer 8 is visible. The view shown in FIG. 4(b) may be a horizontal cross section through the device shown in FIG. 2 along line G-G′. The upper metal layer 8 forms an emitter matrix layer that covers almost all the usable chip area, and thus has an increased surface area compared to state-of-the-art devices.

In comparison to state-of-the-art devices, there is no requirement for the active area of the device to be reduced in size to provide a region for an emitter bond area, as the metal layer 8 can be formed directly over the emitter contacts 6B in the active area of the device. This allows the size of the active area of the device to be significantly increased.

By having the base contact 10 only under a base pad, and the emitter matrix over the larger chip area, the device has an improved ESD performance.

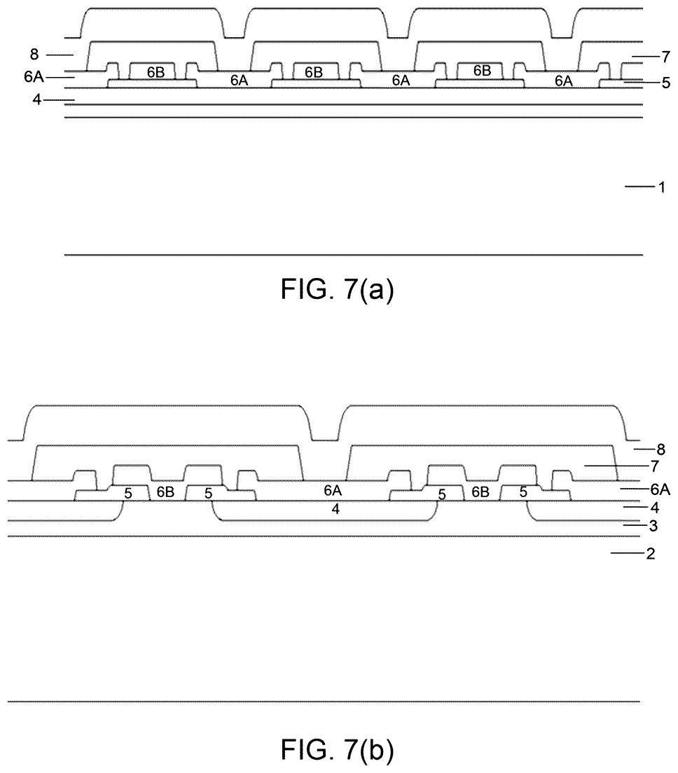

FIG. 7(a) shows a cross-sectional view along line D-D′ of the BJT device shown in FIG. 6 according to some embodiments of the present disclosure. The view of FIG. 7(a) is similar to that shown in FIG. 3. FIG. 7(b) shows an alternative cross-sectional view along the diagonal line C-C′ of the BJT device shown in FIG. 6 according to some embodiments of the present disclosure. The view of FIG. 7(b) is similar to that shown in FIG. 2. The features are similar to those shown in FIGS. 2 and 3, and therefore carry the same reference numerals.

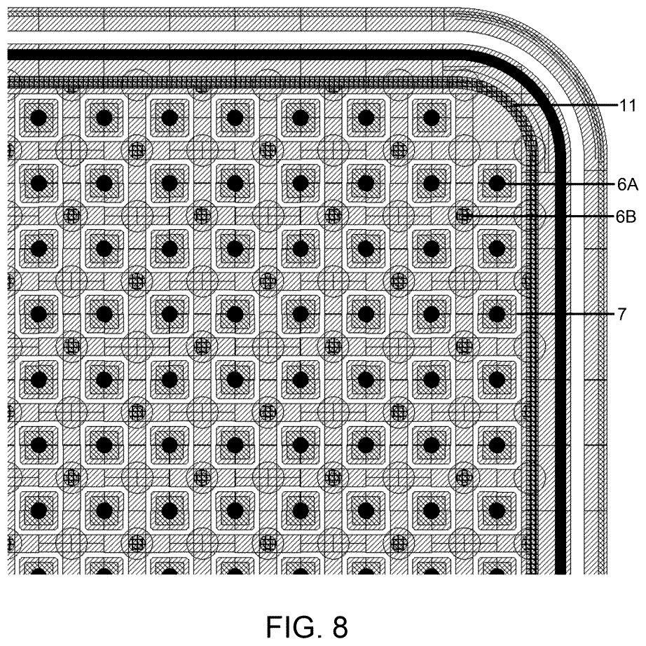

FIG. 8 shows a magnified top-view of an alternative BJT according to an embodiment of the disclosure. In this view, the upper metal contact layer 8 has been omitted. In this example, the base contacts 6B are arranged in a grid pattern. While not shown, the connections from the base contacts 6B to the metal track 11 are arranged in a mesh grid pattern. This further reduces the connection distance between the base contacts 6B and the metal track 11. Thereby further improving uniformity of on-state operation across the device, and reducing turn-off speed.

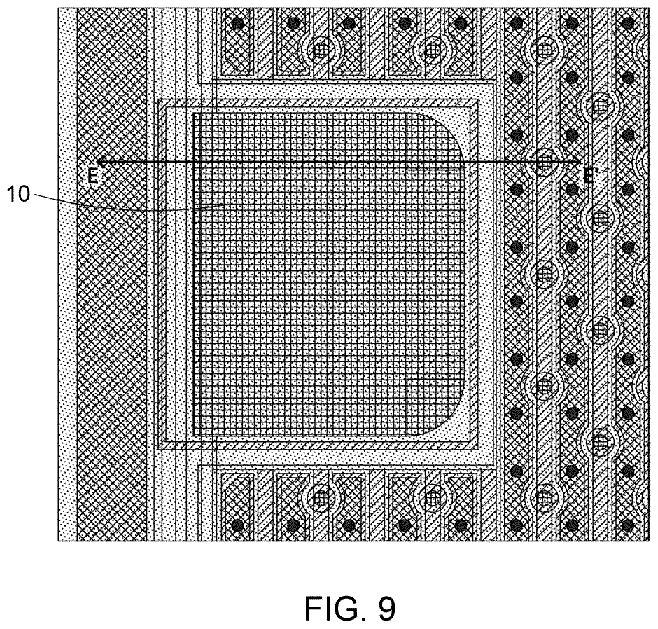

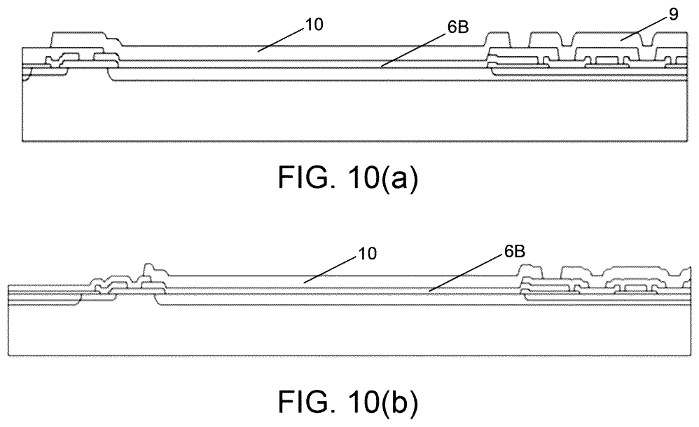

FIG. 9 shows a magnified top-view of the base pad area of the BJT shown in FIGS. 4(a) and 4(b). The base pad 10 comprises a top metal layer that is connected to a base metal contact 6B. The base pad 10 and the base metal contact 6B in the base pad area have a larger area than the other base metal contacts 6B throughout the device. The base pad 10 is laterally spaced and insulated from the top metal layer 9. FIG. 10(a) illustrates a cross-section through the device shown in FIG. 9 across the diagonal line E-E′. FIG. 10(b) illustrates an alternative cross-section through the device shown in FIG. 9 across the diagonal line E-E′. Although the cross-section shown in FIG. 10(b) is not shown as planarized, it would be understood that this embodiment may alternatively be planarized.

It will be understood that while the examples shown describe a n-p-n BJT device, the principles can also apply to a p-n-p BJT device. It will also be understood that while FIGS. 5 and 8 show two patterns of connections to the base contacts 6B, the invention is not limited to these two patterns.

In embodiments of the herein disclosed device, the BJT device 100 features a large unbroken sheet of top metal 8, connected to the emitter region 4 of the transistor. Unlike existing semiconductor chips incorporating bipolar junction transistors, this allows a larger region of emitter-connected metal large enough without compromising the efficient delivery of base current, and/or delete active emitter area. The large unbroken area of the emitter metal contact on the top surface of the device is suitable for connecting to bond wires, a ribbon bond or a clip bond.

In some embodiments, emitter bond wires comprise circular cross-section wires generally formed of gold or copper, though they may comprise other materials. They are generally ultrasonically bonded to the emitter contact 8 of the device. In some examples, multiple wires can be bonded in parallel, to reduce the overall resistance contribution. Generally, 43 μm diameter Copper wires may be used, each with a cross-sectional area of 1849 μm².

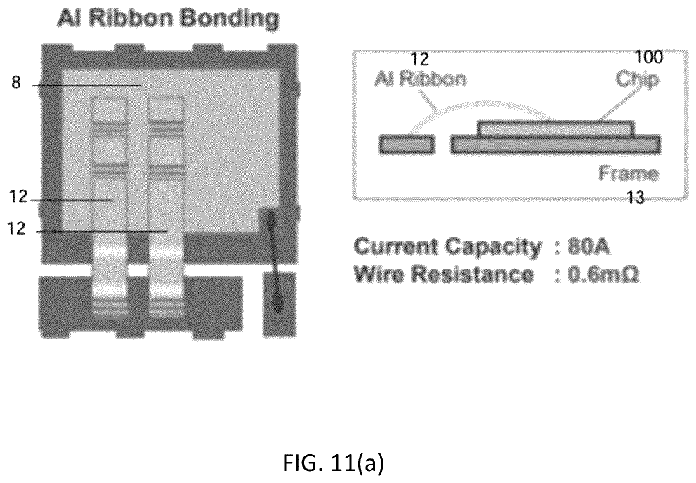

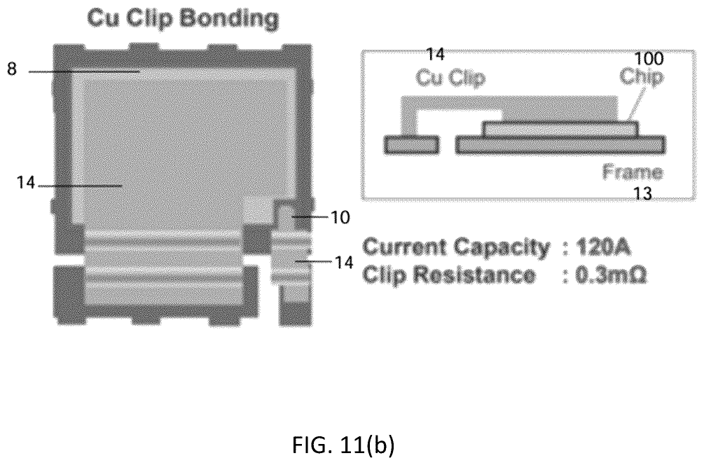

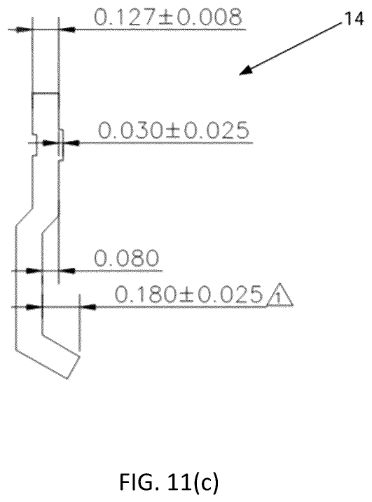

Alternatively, an emitter ribbon bond includes a rectangular cross-section ribbon 12, such as shown in FIG. 11(a). FIG. 11(a) illustrates schematically a top-view and side-view of a ribbon bond 12 to a BJT device 100 arranged on a frame 13. This is generally formed of Aluminum, though other metal materials may be used. Each ribbon bond has significantly greater cross-sectional area versus individual wires. In embodiments, ribbon of 762 μm width and 101 μm uncompressed height may be used. In some embodiments, a ribbon bond of smaller width may be used, for example having a width of 508 μm. The ribbon bond may have a first uncompressed height before bonding to the semiconductor chip, and a second, larger area in contact with the semiconductor chip after being bonded to the semiconductor chip. For example, a ribbon of 762 μm width and 101 μm uncompressed height before bonding, may have a contact area of 762 μm in width and 304 μm in length in contact with the semiconductor chip.

The herein disclosed structure of the bipolar junction transistor allows larger semiconductor chips to be formed. In some examples, to facilitate ribbon bonding and/or clip bonding, an edge of the semiconductor chip may have a length of at least 0.25 mm, more preferably at least 0.5 mm, or even more preferably at least 1 mm. It is preferably for the ribbon bond not to be formed between cells.

Alternatively, an emitter clip bond 14 is shown in FIGS. 11(b) and 11 (c). FIG. 11(b) shows schematically a top-view and side view of clip bonding to a BJT device 100 arranged on a frame 13 as disclosed herein according to some embodiments of the present disclosure. This includes a metal sheet (for example, copper) configured to be welded or soldered to the top emitter metal layer 8 of the semiconductor chip. The metal sheet forming the clip 14 is shaped to be substantially congruent to the top emitter metal contact 8 of the device. This means that the contact area between the clip bond 14 and the semiconductor chip is increased compared to other methods of electrical connection, and thus the electrical resistance through the clip bond reduced compared to other methods of electrical connection including ribbon bonding. The metal sheet used for the clip bond may typically have a thickness or uncompressed height of 152 μm (as compared to the 101 μm thickness of an Al ribbon bond).

The clip bond may have a first uncompressed height before bonding to the semiconductor chip, and a second, larger area in contact with the semiconductor chip after being bonded to the semiconductor chip. For example, a clip bond of 830 μm width and 152 μm before bonding, may have a contact area of 830 μm in width and 555 μm in length in contact with the semiconductor chip after bonding.

Clip bonds, and in some examples ribbon bonds, may have a smaller width than the embodiments discussed above. However, reducing the size of the bond and the semiconductor chip means that it can handle reduced current. This reduces the advantage of using a ribbon or clip bond.

FIG. 11(b) illustrates a device in which the emitter contacts 6A are connected to external circuity via clip bonding through the metal contact layer 8, while the base contacts 6B are separately connected to external circuity via clip bonding through the base pad 10. Alternatively, different connection methods may be used for the emitter contacts 6A and base contacts 6B. For example, the emitter contacts 6A may be connected to external circuity through the metal contact layer 8 via clip bonding, while the base contacts 6B may be connected to external circuity through the base pad 10 using wire bonding or other type of connection.

To connect the clip bond to the top metal layer of BJT device, the device can further include a solderable top metal top liner; this may comprise a layer of silver or gold. The herein used clip bond structure improves current capacity and package resistance of the device.

FIG. 11 (c) shows a side view of a metal sheet (also referred to as a clip) for use in clip bonding. In the illustrated example of FIG. 11 (c), the clip has a thickness of 127 μm before bonding. However, in other embodiments, the clip may have different thicknesses, such as 152 μm, 203 μm, or other suitable dimensions depending on the application. In some embodiments, the clip may be formed of steel (such as stainless steel). In other embodiments, the clip may be formed of other metals, such as copper.

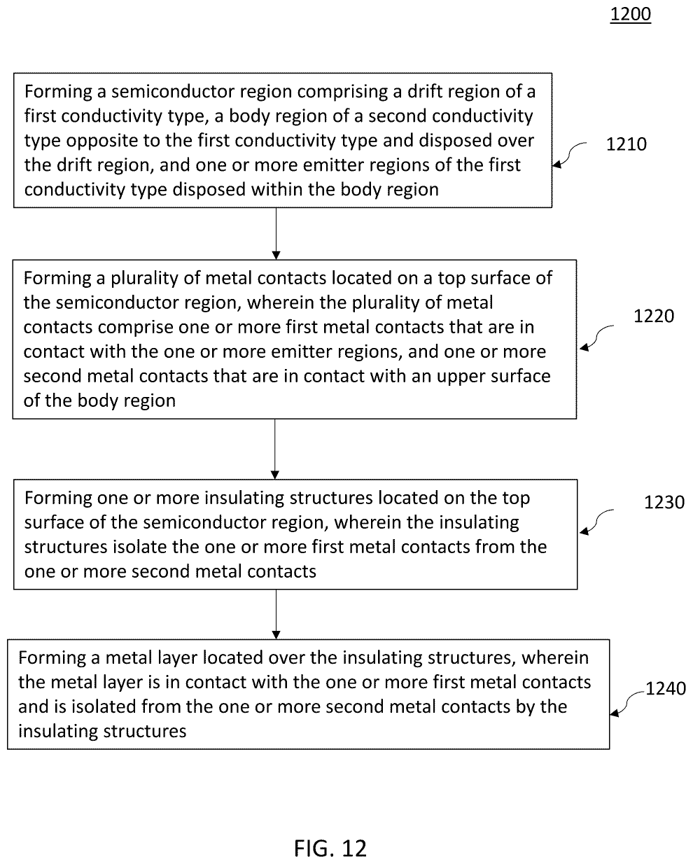

FIG. 12 illustrates a flow chart of a method 1200 for manufacturing a BJT device according to some embodiments of the present disclosure. It should be understood that the example method shown in FIG. 12 is merely an example of many possible example methods. One of ordinary skill in the art would recognize many variations, alternatives, and modifications. For example, various steps as illustrated in FIG. 12 may be added, removed, replaced, rearranged, or repeated.

At step 1210, forming a semiconductor region comprising a drift region of a first conductivity type, a body region of a second conductivity type opposite to the first conductivity type and disposed over the drift region, and one or more emitter regions of the first conductivity type disposed within the body region.

At step 1220, forming a plurality of metal contacts located on a top surface of the semiconductor region, wherein the plurality of metal contacts comprise one or more first metal contacts that are in contact with the one or more emitter regions, and one or more second metal contacts that are in contact with an upper surface of the body region.

At step 1230, forming one or more insulating structures located on the top surface of the semiconductor region, wherein the insulating structures isolate the one or more first metal contacts from the one or more second metal contacts.

At step 1240, forming a metal layer located over the insulating structures, wherein the metal layer is in contact with the one or more first metal contacts and is isolated from the one or more second metal contacts by the insulating structures.

In some embodiments, forming the one or more insulating structures comprises forming one or more dielectric regions comprising an upper dielectric region supported by two or more laterally spaced columnar structures, and wherein the upper dielectric region has a thickness that is at least half the width of the columnar structures.

In some embodiments, after forming the one or more dielectric regions, the method further comprises planarizing an upper surface of the upper dielectric region.

Features described in the context of one embodiment may be used in combination with other embodiments. For example, each of the optional features described above in the context of the apparatus may be used in combination with the method.

According to the structures and processes disclosed above, steps in the aforementioned processes can be adjusted or reordered while maintaining the same objectives and concepts, in order to achieve the same or similar semiconductor structures.

In this disclosure, spatial relative terms such as “below,” “beneath,” “lower,” “above,” “upper,” “left,” “right,” “on”, etc., are used to describe the relationships between one component or feature and one or more other components or features as depicted in the figures. Aside from the orientations depicted in the figures, these spatial relative terms are also intended to cover different operational orientations of the device. The device can be oriented in other ways (e.g., rotated 90 degrees or placed in other orientations), and the spatial relative descriptions used herein are intended to be interpreted correspondingly. It should be understood that when a component is said to be “connected to” or “coupled to” another component, it can be directly connected or coupled to the other component, or intervening components may be present.

As used herein, terms like “approximately,” “substantially,” and “about” are used to describe and account for small variations. When used in conjunction with an event or circumstance, these terms can refer to the precise occurrence of the event or circumstance as well as instances that are close to such occurrence. As used herein concerning given values or ranges, the term “about” generally means within ±10%, ±5%, ±1%, or ±0.5% of a given value or range. Ranges can be expressed as from one endpoint to another endpoint, or encompassing everything between two endpoints. All ranges disclosed herein include their endpoints unless otherwise specified. The term “substantially coplanar” may refer to two surfaces that are positioned along the same plane with a positional difference of a few micrometers (μm), such as within 10 μm, 5 μm, 1 μm, or 0.5 μm. When numerical values or characteristics are described as “substantially” the same, the terms may denote values within ±10%, ±5%, ±1%, or ±0.5% of the stated average value.

The foregoing content outlines several embodiments' features and the detailed aspects of this disclosure. The embodiments described herein can readily serve as the basis for designing or modifying other processes and structures to achieve similar purposes or to attain the advantages introduced by the embodiments discussed.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A bipolar junction transistor (BJT) comprising:
a semiconductor region, comprising:
a drift region of a first conductivity type;
a body region of a second conductivity type, opposite to the first conductivity type, disposed over the drift region;
one or more emitter regions of a first conductivity type disposed within the body region; and
a plurality of metal contacts, located on a top surface of the semiconductor region, wherein the plurality of metal contacts comprise one or more first metal contacts that are in contact with the one or more emitter regions and one or more second metal contacts that are in contact with an upper surface of the body region;
one or more insulating structures located on the top surface of the semiconductor region, wherein the insulating structures isolate the one or more first metal contacts from the one or more second metal contacts; and
a metal layer located over the insulating structures, wherein the metal layer is in contact with one or more first metal contacts and is isolated from the one or more second metal contacts by the insulating structures.

2. A bipolar junction transistor according to claim 1, wherein the one or more first metal contacts and the one or more second metal contacts are laterally spaced from each other in a first direction, and wherein the one or more second metal contacts are vertically spaced from the metal layer in a second direction, wherein the second direction is perpendicular to the first direction.

3. A bipolar junction transistor according to claim 2, wherein the bipolar junction transistor is configured such that, when in use, current flows vertically between the one or more first metal contacts and the metal layer, and current flows within the one or more second metal contacts laterally through the bipolar junction transistor.

4. A bipolar junction transistor according to claim 3, comprising a base terminal, and wherein the one or more second metal contacts are connected to the base terminal via a metal track extending along a perimeter of the bipolar junction transistor.

5. A bipolar junction transistor according to claim 4, wherein each second metal contact of the one or more second metal contacts is connected to the metal track via a plurality of connections extending in at least two different directions.

6. A bipolar junction transistor according to claim 5, wherein each second metal contact of the one or more second metal contacts is directly connected to a portion of the metal track extending along a side of the bipolar junction transistor that is closest to said each second metal contact of the one or more second metal contacts.

7. A bipolar junction transistor according to claim 1, wherein the one or more insulating structures comprise:
a plurality of first insulating regions located on the top surface of the semiconductor region, wherein each first insulating region is located laterally between a first metal contact of the one or more first metal contacts and a second metal contact of the one or more second metal contacts; and
one or more dielectric regions located over the one or more second metal contacts, wherein the one or more dielectric regions are at least partly located over the plurality of first insulating regions and overlap an upper surface of the one or more first metal contacts.

8. A bipolar junction transistor according to claim 7, wherein the one or more dielectric regions comprises an upper dielectric region supported by two or more laterally spaced columnar structures, wherein a lower surface of each columnar structure is in contact with an upper surface of a first insulating region of the plurality of first insulating regions.

9. A bipolar junction transistor according to claim 8, wherein a width of the two or more columnar structures is at least 2 μm.

10. A bipolar junction transistor according to claim 8, wherein an upper surface of the one or more dielectric regions is planarized.

11. A bipolar junction transistor according to claim 7, wherein the insulating structures are formed of silicon dioxide.

12. A bipolar junction transistor according to claim 7, wherein the metal layer has a larger surface area than the one or more first metal contacts.

13. A bipolar junction transistor according to claim 7, further comprising a ribbon bond formed over the metal layer.

14. A bipolar junction transistor according to claim 7, further comprising a clip bond formed over the metal layer.

15. A bipolar junction transistor according to claim 1, wherein a spacing between adjacent second metal contacts of the one or more second metal contacts is between 35 μm to 50 μm.

16. A bipolar junction transistor according to claim 1, wherein an emitter terminal connection is formed on an upper surface of the bipolar junction transistor over the metal layer and extending substantially over the active area of the bipolar junction transistor.

17. A bipolar junction transistor according to claim 16, further comprising a base terminal connection formed on the upper surface of the bipolar junction transistor, wherein the base terminal connection does not extend over the metal layer.

18. A method of manufacturing a bipolar junction transistor (BJT), the method comprising:
forming a semiconductor region, comprising:
a drift region of a first conductivity type;
a body region of a second conductivity type, opposite to the first conductivity type, disposed over the drift region; and
one or more emitter regions of the first conductivity type disposed within the body region; and
forming a plurality of metal contacts, located on a top surface of the semiconductor region, wherein the plurality of metal contacts comprise one or more first metal contacts that are in contact with the one or more emitter regions and one or more second metal contacts that are in contact with an upper surface of the body region;
forming one or more insulating structures located on the top surface of the semiconductor region, wherein the insulating structures isolate the one or more first metal contacts from the one or more second metal contacts; and
forming a metal layer located over the insulating structures, wherein the metal layer is in contact with the one or more first metal contacts and is isolated from the one or more second metal contacts by the insulating structures.

19. A method according to claim 18, wherein forming the one or more insulating structures comprises forming one or more dielectric regions comprising an upper dielectric region supported by two or more laterally spaced columnar structures, and wherein the upper dielectric region has a thickness that is at least half the width of the columnar structures.

20. A method according to claim 19, wherein after forming the one or more dielectric regions, the method further comprises planarizing an upper surface of the upper dielectric region.
